(19) United States
(12) Patent Application Publication
(10) Pub. No.: US 2009/0023080 A1
(43) Pub. Date: Jan. 22, 2009

(54) MASK AND MANUFACTURING METHOD THEREOF

(76) Inventor: Yeon-Ah Shim, Hampyeong-gun (KR)

Correspondence Address: SHERR & VAUGHN, PLLC, 620 HERNDON PARKWAY, SUITE 200, HERNDON, VA, 20170, US

(21) Appl. No.: 12/169,592

(22) Filed: Jul. 8, 2008

(30) Foreign Application Priority Data
Jul. 20, 2007 (KR) 10-2007-0072639

(51) Int. Cl. G03F 7/004

(52) U.S. Cl. 430/5

(57) ABSTRACT

A mask according to embodiments includes a substrate and a phase delay material layer formed over the substrate. At least one mask pattern including a hole pattern may be formed on the phase delay material layer, the hole pattern allowing light to pass through the mask pattern. Assist patterns compensate for constructive interference of the light occurring between the mask patterns. Embodiments may prevent sidelobes from occurring by inserting an assist pattern into a mask, so that defects in semiconductor devices can be prevented.

The present application claims priority under 35 U.S.C. 119 to Korean Patent Application No. 10-2007-0072639 (filed on Jul. 20, 2007), which is hereby incorporated by reference in its entirety.

### BACKGROUND

Photolithography processes are essential for manufacturing semiconductor devices. In a photolithography process, after coating a relatively uniform photoresist layer over a wafer, the wafer is subject to an exposure process using a photomask having a predetermined layout. Then the exposed photoresist layer is developed to form a pattern having a predetermined shape.

In semiconductor photolithography technologies used for manufacturing semiconductor devices, a mask may be precisely designed such that the amount of light passing through the mask can be precisely adjusted. As semiconductor devices have become more highly integrated, design rules for smaller scale devices have been introduced. At smaller scales, sidelobes may occur between adjacent patterns due to constructive interference of light.

FIG. 1A is a plan view illustrating a part of a related mask, FIG. 1B is a view illustrating an aerial image of light passing through the mask of FIG. 1A, and FIG. 1C is a view illustrating patterns formed using the mask of FIG. 1A. As shown in FIG. 1A, the related mask 10 has mask patterns 11, such as hole patterns or blocking patterns, corresponding to photoresist patterns to be formed. When mask 10 includes hole patterns 11, as shown in FIG. 1B, sidelobe 23 may occur in the aerial image of light, which passes through mask patterns 11, due to constructive interference of light. As shown in FIG. 1C, an undesired sidelobe pattern 33 may be generated between the photoresist patterns 31 to be formed over a substrate 30 through the mask 10. Thus, when the photoresist patterns 31 are etched using the mask 10, an undesirable result may be generated by the sidelobe pattern 33 on the substrate 30.

### SUMMARY

Embodiments relate to a mask capable of preventing sidelobes from being formed in a photoresist pattern used for forming a semiconductor device, and a manufacturing method thereof. A mask according to embodiments includes a substrate and a phase delay material layer formed over the substrate. At least one mask pattern including a hole pattern may be formed on the phase delay material layer, the hole pattern allowing light to pass through the mask pattern. Assist patterns compensate for constructive interference of the light occurring between the mask patterns.

A method for manufacturing a mask according to embodiments includes preparing a base substrate and forming a phase delay material layer over the base substrate. The method includes forming at least one mask pattern including a first hole pattern, which allows light to pass through the hole pattern, by patterning the phase delay material layer. The method includes forming at least one assist pattern including a second hole pattern located between the mask patterns, thereby compensating for constructive interference of the light between portions of the first hole pattern.

A phase shift mask having a light phase delay part and light transmitting parts according to embodiments includes at least one hole pattern formed on a light phase delay part between the light transmitting parts in a phase shift mask, the hole pattern causing destructive interference of a portion of the light passing through the light transmitting parts.

Embodiments can prevent undesirable sidelobes, which may be formed in a dense photoresist pattern, from occurring, so that desirable patterns may be formed. Embodiments may prevent sidelobes from occurring by inserting an assist pattern into a mask, so that defects in semiconductor devices can be prevented.

### DRAWINGS

FIG. 1A is a plan view illustrating a part of a related mask.

FIG. 1B is a view illustrating an aerial image of light passing through the mask of FIG. 1A.

FIG. 1C is a view illustrating patterns formed using the mask of FIG. 1A.

FIG. 2 is a sectional view illustrating a mask according to embodiments.

FIG. 3A is a sectional view illustrating a pattern formed using the mask of FIG. 2 according to embodiments.

FIG. 3B is a sectional view illustrating a pattern formed using the mask of FIG. 2 according to embodiments.

FIG. 4A is a plan view illustrating a part of a mask according to embodiments.

FIG. 4B is a view illustrating an aerial image of light passing through the mask of FIG. 4A.

FIG. 4C is a view illustrating a pattern formed using the mask of FIG. 4A.

FIG. 5A is a plan view illustrating a mask according to embodiments.

FIG. 5B is a plan view illustrating a comparison mask compared with a mask according to embodiments.

FIG. 6 is a graph illustrating intensity of light, which passes through the mask of FIGS. 5A and 5B, as a function of positions “a-b” of the mask.

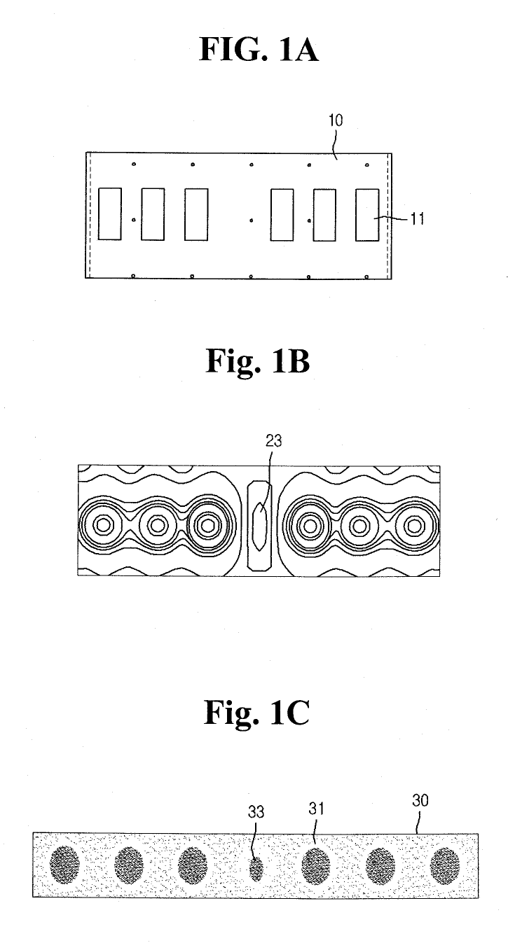

### DESCRIPTION

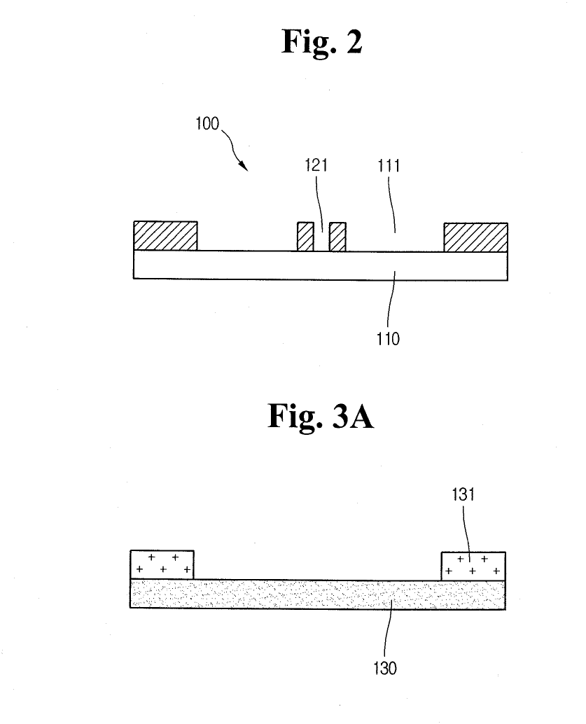

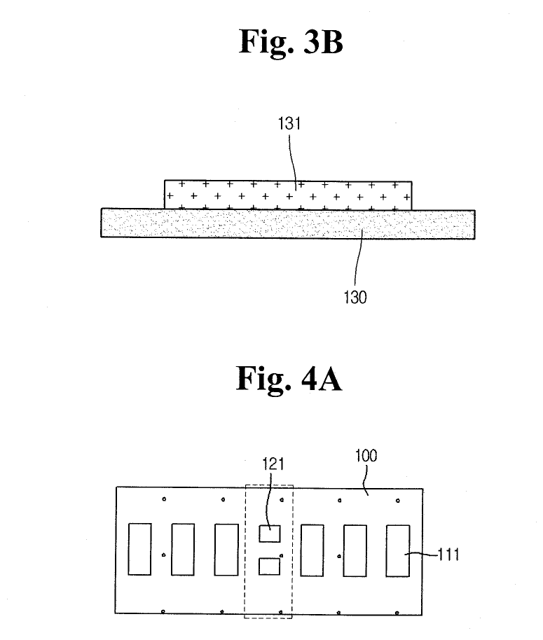

Hereinafter, a mask and a manufacturing method thereof according to embodiments will be described with reference to the accompanying drawings. FIG. 2 is a sectional view illustrating a mask according to embodiments. FIG. 3A is a sectional view illustrating a pattern formed using the mask of FIG. 2 according to embodiments. and FIG. 3B is a sectional view illustrating a pattern formed using the mask of FIG. 2 according to embodiments. As shown in FIG. 2, the mask 100 according to embodiments includes a base substrate 110, mask patterns 111 and assist patterns 121. The mask patterns 111 and the assist patterns 121 may be formed on a base substrate 110. The mask 100 may include a PSM (Phase Shift Mask). The mask pattern 111 may include a hole pattern or a blocking pattern.

Referring to FIG. 2, the mask pattern 111 includes a hole pattern to serve as a light transmitting part. A peripheral area of the mask pattern 111 may serve as a light phase delay part. The light phase delay part may include a phase delay material layer. The phase delay material layer may be a compound, for example, compounds containing transition metals. The transition metal may include one selected from the group consisting of Cr, Mo, Hf, W, Pt, Co, Ni, Ta and Ti. Further, the compound including the transition metal may include Si.

The assist pattern 121 prevents one or more sidelobes which may occur due to constructive interference generated between the mask patterns 111. The assist pattern 121 may cause destructive interference, which compensates for the constructive interference, by allowing light to pass through a place where the sidelobe occurs. When the mask pattern 111 includes a hole pattern, the assist pattern 121 may be formed with a hole pattern. Further, when the mask pattern 111 includes a blocking pattern, the assist pattern 121 may be formed with a blocking pattern. The assist pattern 121 may have a size corresponding to 20% to 60% of that of the mask pattern 111. Further, an interval between the assist patterns 121 may correspond to 50% to 200% of the size of the assist pattern 121.

An arrangement interval of the mask patterns 111 may be larger than a width of the mask pattern 111 by one to ten times. The assist pattern 121 may have a circular or polygonal shape. Further, by way of example, the assist pattern 121 may also have a triangular, rectangular or pentagonal shape. The assist pattern 121 may include slits. In other words, the assist pattern 121 may have various shapes which may effectively remove the sidelobe(s).

As shown in FIGS. 3A and 3B, when the photolithography process is performed using the mask 100, good photoresist patterns 131 can be formed over the substrate 130. FIG. 3A is a sectional view illustrating a mask when positive photoresist is used and FIG. 3B is a sectional view illustrating the mask when negative photoresist is used. Since destructive interference occurs in the mask due to the assist pattern 121 formed between the mask patterns 111, a sidelobe pattern is not generated between the photoresist patterns 131 formed by the mask patterns 111.

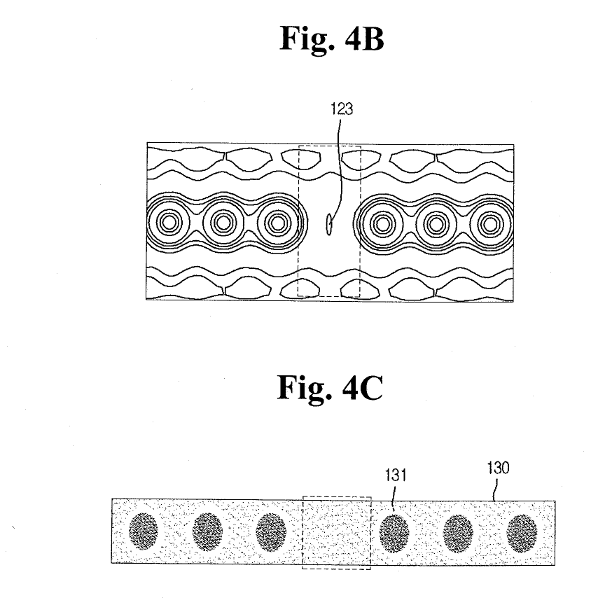

FIG. 4A is a plan view illustrating a part of the mask according to embodiments. FIG. 4B is a view illustrating an aerial image of light passing through the mask of FIG. 4A. FIG. 4C is a view illustrating a pattern formed using the mask of FIG. 4A. As shown in FIG. 4A, the mask 100 according to embodiments includes mask patterns 111, such as hole patterns or blocking patterns, corresponding to the photoresist pattern 131 to be formed. Further, the mask 100 includes the assist pattern 121 between the mask patterns 111. Light diffraction may occur when the light passes through the assist pattern 121, so that destructive interference of light may occur.

As shown in FIG. 4B, in view of the aerial image of light passing through the mask patterns 111 and the assist patterns 121, the light passes through the mask patterns 111, but the light forms a minimal image 123 corresponding to the assist patterns 121 due to the destructive interference of light. Thus, as shown in FIG. 4C, an undesirable sidelobe pattern, except for patterns formed by the mask patterns 111, is not formed between the photoresist patterns 131 formed over the substrate 130 through the mask 100.

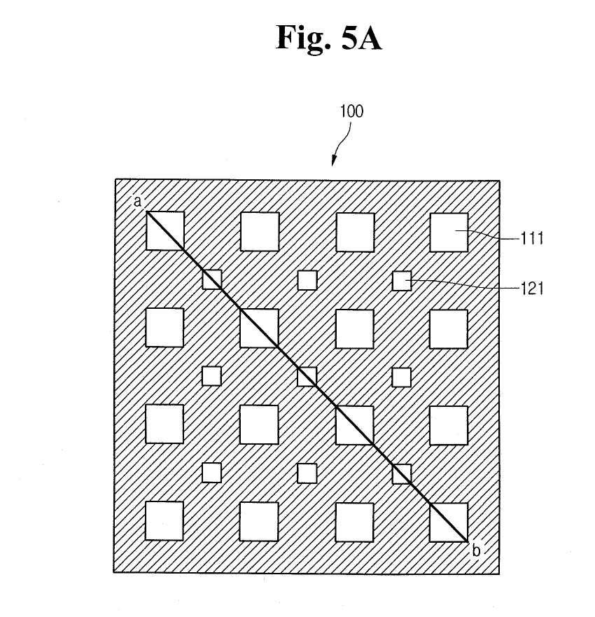

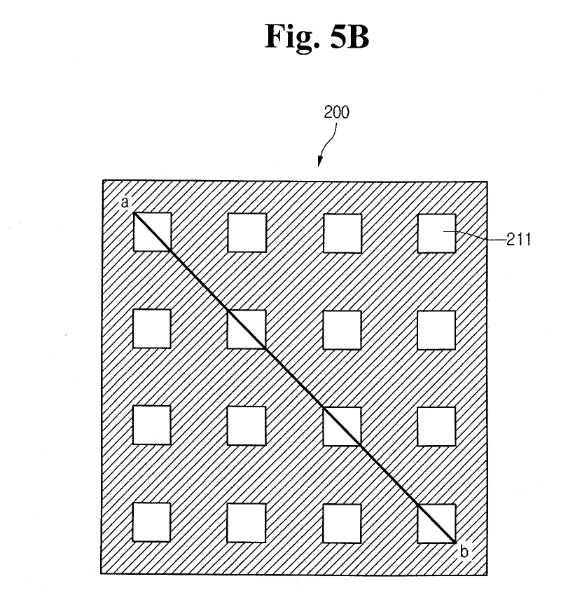

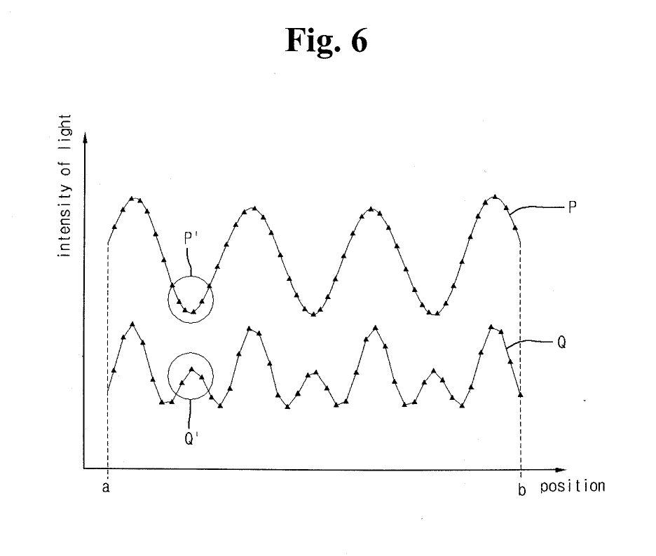

FIG. 5A is a plan view illustrating the mask according to embodiments. FIG. 5B is a plan view illustrating a comparison mask compared with the mask according to embodiments. FIG. 6 is a graph illustrating the intensity of light, which passes through the mask of FIGS. 5A and 5B, as a function of positions along the line shown between points “a” and “b” on the masks. As shown in FIG. 5A, the mask 100 according to embodiments includes mask patterns 111 formed with hole patterns and the assist patterns 121. As shown in FIG. 5B, the comparison mask 200 includes comparison mask patterns 211 identical to the mask patterns 111 of the mask 100 according to embodiments, and does not include assist patterns.

The graphs with curves indicated by P and Q in FIG. 6 can be obtained by measuring the intensity of light passing through the mask 100 and the comparison mask 200, respectively. As shown on curve P of the mask 100, the maximum intensity of light is obtained at the position corresponding to the mask patterns 111, and intensity of light is lowered at the position P′ corresponding to the assist patterns 121 due to the destructive interference of the light. As shown on curve Q of the comparison mask 200, the maximum intensity of light is obtained at the position corresponding to the comparison mask patterns 211, and a relatively lower local maximum intensity of light is obtained by the constructive interference of the light at the position Q′ corresponding to the mask between the comparison mask patterns 211.

In view of photoresist corresponding to the comparison mask 200, light does not physically pass through the mask between the comparison mask patterns 211. From an optical point of view, a sufficient amount of light is irradiated onto the photoresist, so that an undesirable sidelobe pattern may be formed over the substrate. However, in view of photoresist corresponding to the mask 100 according to embodiments, light physically passes through the assist patterns 121. From an optical point of view, destructive interference occurs when the light passes through the assist patterns 121, so that the sidelobe pattern is not formed on the photoresist. Consequently, only desired patterns may be formed over the substrate.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a substrate;
a phase delay material layer formed over the substrate;
at least one mask pattern including a hole pattern on the phase delay material layer, the hole pattern allowing light to pass through the mask pattern; and
assist patterns compensating for constructive interference of the light occurring between the mask patterns.

2. The apparatus of claim 1, wherein the phase delay material layer includes a compound comprising at least one transition metal.

3. The apparatus of claim 2, wherein the transition metal includes at least one selected from the group consisting of Cr, Mo, Hf, W, Pt, Co, Ni, Ta and Ti.

4. The apparatus of claim 2, wherein the compound including a transition metal also includes Si.

5. The apparatus of claim 1, wherein the assist pattern has a size corresponding to 20% to 60% of a size of the mask pattern.

6. The apparatus of claim 1, wherein an interval between the assist patterns corresponds to 50% to 200% of a size of the assist pattern.

7. The apparatus of claim 1, wherein the light passing through the mask pattern exposes a photoresist layer to form a pattern, and light passing through the assist pattern does not substantially form a pattern over the photoresist layer.

8. The apparatus of claim 7, wherein light passing through the assist pattern destructively interferes with a portion of the light passing through the mask pattern.

9. The apparatus of claim 1, wherein the assist pattern includes slits.

10. The apparatus of claim 1, wherein the assist pattern has one of a circular shape and a polygonal shape.

11. The apparatus of claim 1, wherein an arrangement interval of the mask patterns is larger than a width of the mask pattern by one to ten times.

12. A method comprising:
preparing a base substrate;
forming a phase delay material layer over the base substrate;
forming at least one mask pattern including a first hole pattern, which allows light to pass through the hole pattern, by patterning the phase delay material layer; and
forming at least one assist pattern including a second hole pattern located between the mask patterns, thereby compensating for constructive interference of the light between portions of the first hole pattern.

13. The method of claim 12, wherein the phase delay material layer includes at least one selected from the group consisting of Cr, Mo, Hf, W, Pt, Co, Ni, Ta and Ti.

14. The method of claim 13, wherein the phase delay material layer including a transition metal also includes Si.

15. The method of claim 12, wherein the assist pattern has a size corresponding to 20% to 60% of a size of the mask pattern.

16. The method of claim 12, wherein an interval between the assist patterns corresponds to 50% to 200% of a size of the assist pattern.

17. An apparatus comprising:
at least one hole pattern formed on a light phase delay part between the light transmitting parts in a phase shift mask, the hole pattern causing destructive interference of a portion of the light passing through the light transmitting parts.

18. The apparatus of claim 17, wherein the hole pattern has a size corresponding to 20% to 60% of a size of the light transmitting part.

19. The apparatus of claim 17, wherein the light phase delay part includes a transition metal compound having at least one selected from the group consisting of Cr, Mo, Hf, W, Pt, Co, Ni, Ta and Ti.

20. The apparatus of claim 19, wherein the transition metal compound also includes Si.
